(19) United States
(12) Patent Application Publication
(10) Pub. No.: US 2011/0073840 A1
(43) Pub. Date: Mar. 31, 2011

(54) RADIAL CONTACT FOR NANOWIRES

(75) Inventors: Michael L. Chabinyc, Santa Barbara, CA (US); William S. Wong, San Carlos, CA (US); Sourobh Raychaudhuri, Palo Alto, CA (US)

(73) Assignee: PALO ALTO RESEARCH CENTER INCORPORATED, Palo Alto, CA (US)

(21) Appl. No.: 12/571,339

(22) Filed: Sep. 30, 2009

(51) Int. Cl. H01L 29/66; H01L 21/336

(52) U.S. Cl. 257/24; 438/197; 257/E29.168; 257/E21.409

(57) ABSTRACT

An embodiment is a method and apparatus of radial contact using nanowires. An inner contact has a center. An outer contact surrounds the inner contact around the center and is spaced from the inner contact by a channel length. A nanowire connects the center of the inner contact and the outer contact in a rotationally invariant geometry.

Another embodiment is a method and apparatus of a semiconductor device with bottom gate structure and having radial contact using nanowires. A gate electrode is deposited on a substrate. A dielectric layer is deposited on the substrate and the gate electrode. A source-drain assembly is deposited on the dielectric layer. The source-drain assembly has source and drain electrodes connected via a nanowire in a rotationally invariant geometry.

Another embodiment is a method and apparatus of a semiconductor device with top gate structure and having radial contact using nanowires. An isolation barrier layer is deposited on a substrate. A source-drain assembly is deposited on the substrate and within the isolation barrier layer. The source-drain assembly has source and drain electrodes connected via a nanowire in a rotationally invariant geometry. A dielectric layer is deposited on the source-drain assembly. A gate electrode is deposited on the dielectric layer.

Another embodiment is a method and apparatus of a semiconductor device having radial contact using nanowires of short lengths. Source and drain electrodes are fabricated having a contact structure with a rotationally invariant geometry. The contact structure has inner and outer contacts corresponding to the source and drain electrodes, respectively. The outer contact is spaced from the inner contact by a channel length. Wells are formed in vicinity of the contact structure. A suspension is placed in the wells. The suspension has single or multiple nanowires having a short length in a liquid. An alternating current (AC) source is applied to the contact structure to cause the single or multiple nanowires to align and connect the inner contact to the outer contact. The AC source has a first terminal connected to the inner contact and a second terminal not connected to the inner and outer contacts.

### TECHNICAL FIELD

The presently disclosed embodiments are directed to the field of semiconductor devices, and more specifically, to nanowires.

### BACKGROUND

Currently, there is great interest in growing nanowires of semiconducting materials on a growth substrate and then transferring them to a final substrate to form electronic devices. These nanowires generally have a high aspect ratio, e.g., 10-50 nm in radius and >5 micron long. Patterning is typically accomplished by deposition of the nanowires in a random, network or by aligning the devices using liquid flow. These methods are limited due to the difficulty of errors in registration of the nanowires to electrode structures that are either previously defined or subsequently patterned by methods such as photolithography.

Single-crystal nanowires and carbon nanotubes have been demonstrated to be useful for high mobility transistors on a variety of substrates. Typically, circuits using these devices are made by spin coating blanket solutions of these nanowires onto a substrate and performing electron-beam lithography to pattern these circuits. These methods are needed because there are few methods to accurately place these wires in any pattern on a substrate. Micro-fluidic channels have been used to deposit these wires with some degree of patterning, but the demonstrations have not been shown to be able to fabricate arbitrary patterns or easily achieve registration. These techniques generally rely on depositing wires over larger areas than desired due relatively poor control of registration and the complexity of building fluidic systems that only contact the substrate in isolated locations. Since the cost of raw materials is important in large area devices, patterning methods that use as little material as possible are desirable.

In all reported work, nanowire devices have been fabricated with linear electrical contacts either in a single pair or in a set of electrodes. If the nanowire and a set of linear contact electrodes are misaligned, the channel length of the device will be affected. The range of angles where there is possible contact depends on the length of the nanowire itself and the length between the contacts. For a typical length of ˜20 micron and a channel length of ˜6 microns, approximately 30% of wires produce devices with no electrical continuity if a random method is used for deposition. If bundles of wires are used, the problem occurs that not all wires will have the same channel length due to their angular dispersion.

### SUMMARY

One disclosed feature of the embodiments is a method and apparatus for radial contact using nanowires. An inner contact has a center. An outer contact circularly surrounds the inner contact around the center and is spaced from the inner contact by a channel length. A nanowire connects the center of the inner contact and the outer contact in a rotationally invariant geometry.

Another disclosed feature of the embodiments is a method and apparatus of a semiconductor device with bottom gate structure and having radial contact using nanowires. A gate electrode is deposited on a substrate. A dielectric layer is deposited on the substrate and the gate electrode. A source-drain assembly is deposited on the dielectric layer. The source-drain assembly has source and drain electrodes connected via a nanowire in a rotationally invariant geometry.

Another disclosed feature of the embodiments is a method and apparatus of a semiconductor device with top gate structure and having radial contact using nanowires. An isolation barrier layer is deposited on a substrate. A source-drain assembly is deposited on the substrate and within the isolation barrier layer. The source-drain assembly has source and drain electrodes connected via a nanowire in a rotationally invariant geometry. A dielectric layer is deposited on the source-drain assembly. A gate electrode is deposited on the dielectric layer.

Another disclosed feature of the embodiment is a method and apparatus of a semiconductor device having radial contact using nanowires of short lengths. Source and drain electrodes are fabricated having a contact structure with a rotationally invariant geometry. The contact structure has inner and outer contacts corresponding to the source and drain electrodes, respectively. The outer contact is spaced from the inner contact by a channel length. Wells are formed in vicinity of the contact structure. A suspension is placed in the wells. The suspension has single or multiple nanowires having a short length in a liquid. An alternating current (AC) source is applied to the contact structure to cause the single or multiple nanowires to align and connect the inner contact to the outer contact. The AC source has a first terminal connected to the inner contact and a second terminal not connected to the inner and outer contacts.

### BRIEF DESCRIPTION OF THE DRAWINGS

Embodiments may best be understood by referring to the following description and accompanying drawings that are used to illustrate various embodiments. In the drawings.

FIG. 1 is a diagram illustrating a contact assembly according to one embodiment.

FIG. 2 is a diagram illustrating a misalignment error curve according to one embodiment.

FIG. 3 is a diagram illustrating a top view of patterned gate electrodes according to one embodiment.

FIG. 4 is a diagram illustrating a side view of patterned gate electrodes according to one embodiment.

FIG. 5 is a diagram illustrating a top view of liquid having nanowires on the patterned gate electrodes according to one embodiment.

FIG. 6 is a diagram illustrating a side view of liquid having nanowires on the patterned gate electrodes according to one embodiment.

FIG. 7 is a diagram illustrating a top view of liquid evaporated leaving nanowires on the patterned gate electrodes according to one embodiment.

FIG. 8 is a diagram illustrating a side view of liquid evaporated leaving nanowires on the patterned gate electrodes according to one embodiment.

FIG. 9 is a diagram illustrating a top view of source and drain electrodes deposited on the gate dielectric according to one embodiment.

FIG. 10 is a diagram illustrating a side view of source and drain electrodes deposited on the gate dielectric according to one embodiment.

FIG. 11 is a diagram illustrating gate electrodes patterned on a substrate according to one embodiment.

FIG. 12 is a diagram illustrating microwells formed on a flexographic plate according to one embodiment.

FIG. 13 is a diagram illustrating liquid deposited into the microwells according to one embodiment.

FIG. 14 is a diagram illustrating the flexographic plate being transferred onto the substrate according to one embodiment.

FIG. 15 is a diagram illustrating a side view of a device having a top gate electrode according to one embodiment.

FIG. 16 is a diagram illustrating a top view of a device having a top gate electrode according to one embodiment.

FIG. 17 is a flowchart illustrating a process to fabricate a device with a bottom gate structure according to one embodiment.

FIG. 18 is a flowchart illustrating a process to pattern source and drain electrodes according to one embodiment.

FIG. 19 is a flowchart illustrating a process to deposit liquid by printing according to one embodiment.

FIG. 20 is a flowchart illustrating a process to fabricate a device with a top gate structure according to one embodiment.

FIG. 21 is a diagram illustrating nanowires having short lengths in random orientation with respect to a pair of electrodes according to one embodiment.

FIG. 22 is a diagram illustrating alignment of nanowires having short lengths with respect to a pair of electrodes using AC source with only one terminal connected to electrodes according to one embodiment.

FIG. 23 is a diagram illustrating alignment of nanowires having short lengths with respect to multiple pairs of electrodes using a single AC source with only one terminal connected to electrodes according to one embodiment.

FIG. 24 is a diagram illustrating nanowires having short lengths in random orientation with respect to electrodes in rotationally invariant geometry according to one embodiment.

FIG. 25 is a diagram illustrating nanowires having short lengths in alignment with respect to electrodes in rotationally invariant geometry using an AC source with only one terminal connected to electrodes according to one embodiment.

FIG. 26 is a flowchart illustrating a process to align nanowires having short lengths according to one embodiment.

FIG. 27 is a diagram illustrating a top view of linear contacts in a prior art embodiment.

FIG. 28 is a diagram illustrating alignment of nanowires using an AC source with two terminals connected to electrodes in a prior art embodiment.

### DETAILED DESCRIPTION

One disclosed feature of the embodiments is a method and apparatus for radial contact using nanowires. An inner contact has a center. An outer contact circularly surrounds the inner contact around the center and is spaced from the inner contact by a channel length. A nanowire connects the center of the inner contact and the outer contact in a rotationally invariant geometry.

Another disclosed feature of the embodiments is a method and apparatus of a semiconductor device with bottom gate structure and having radial contact using nanowires. A gate electrode is deposited on a substrate. A dielectric layer is deposited on the substrate and the gate electrode. A source-drain assembly is deposited on the dielectric layer. The source-drain assembly has source and drain electrodes connected via a nanowire in a rotationally invariant geometry.

Another disclosed feature of the embodiments is a method and apparatus of a semiconductor device with top gate structure and having radial contact using nanowires. An isolation barrier layer is deposited on a substrate. A source-drain assembly is deposited on the substrate and within the isolation barrier layer. The source-drain assembly has source and drain electrodes connected via a nanowire in a rotationally invariant geometry. A dielectric layer is deposited on the source-drain assembly. A gate electrode is deposited on the dielectric layer.

Another disclosed feature of the embodiment is a method and apparatus of a semiconductor device having radial contact using nanowires of short lengths. Source and drain electrodes are fabricated having a contact structure with a rotationally invariant geometry. The contact structure has inner and outer contacts corresponding to the source and drain electrodes, respectively. The outer contact is spaced from the inner contact by a channel length. Wells are formed in vicinity of the contact structure. A suspension is placed in the wells. The suspension has single or multiple nanowires having a short length in a liquid. An alternating current (AC) source is applied to the contact structure to cause the single or multiple nanowires to align and connect the inner contact to the outer contact. The AC source has a first terminal connected to the inner contact and a second terminal not connected to the inner and outer contacts.

Aspects of the embodiments include a radial contact structure that may reduce the need to align nanowires during deposition using methods such as jet printing pr transfer printing. The use of rotationally invariant geometry may allow both rotational mis-alignment and mis-registration with smaller effects in the final device geometry.

One disclosed feature of the embodiments may be described as a process which is usually depicted as a flowchart, a flow diagram, a structure diagram, or a block diagram. Although a flowchart may describe the operations as a sequential process, many of the operations can be performed in parallel or concurrently. In addition, the order of the operations may be re-arranged. A process is terminated when its operations are completed. A process may correspond to a method, a program, a procedure, a method of manufacturing or fabrication, etc. One embodiment may be described by a schematic drawing depicting a physical structure. It is understood that the schematic drawing illustrates the basic concept and may not be scaled or depict the structure in exact proportions.

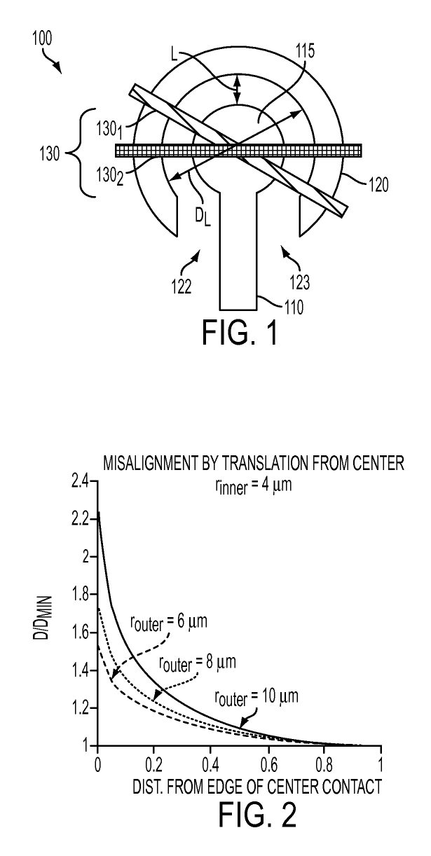

FIG. 1 is a diagram illustrating a contact assembly 100 according to one embodiment. The contact assembly 100 includes an inner contact 110, an outer contact 120, and a nanowire 130. It is noted that the contact assembly 100 may include more or less than the above components.

The inner contact 110 may be a contact having a high electrical conductivity. It may be formed by metal such as copper, or titanium and gold, or molybdenum/chromium, or aluminum, or by a doped semiconductor such as zinc oxide or amorphous silicon. It may correspond to a source or drain electrodes in a semiconductor device. It may include a center 115.

The outer contact 120 may surround the inner contact 110 around the center 115. The surrounding geometry may be circular or any suitable shape such that the entire outer contact 120 encircle or enclose the inner contact 110. The outer contact 120 may enclose the inner contact 110 completely or partially, leaving some opening such as openings 122 and 123. The outer contact 120 may be spaced from the inner contact 110 by a distance L. In one embodiment where the inner contact and the outer contact correspond to source and drain electrodes in a semiconductor device, the distance L may be referred to as a channel length. Depending on the contact geometry, the distance L may be uniform or non-uniform within a pre-defined tolerance. The outer contact 120 may have a largest diameter D_{L}. The largest diameter D_{L} may be the length of the longest line that crosses the center of the outer contact 120 and touches the outer contact 120 at two points on the inner periphery of the outer contact 120. When the outer contact 120 is circularly annular, the largest diameter D_{L} is the inner diameter of the circle. The nanowire 130 has a length and may connect the center 115 of the inner contact 110 and the outer contact 120 in a rotationally invariant geometry. A connection is rotationally invariant may be referred to as a connection uses a rotationally invariant geometry. A rotationally invariant geometry is a geometry in which a connection is maintained, or invariant, regardless of how the nanowire 130 may be rotated. For example, the nanowire 130 may be at a position 130₁ or 130₂. The positions are relative to each other by a rotation of the nanowire 130 around the center 115. In either position, a connection is made between the inner contact 110 and the outer contact 120. Typically, the nanowire 130 may cross the center 115 of the inner contact 110 and connects to at least one point on the outer contact 120 on either side of the center 115. Using this rotationally invariant geometry, the variation in channel length may be significantly less than the traditional linear contacts. In addition, when the radii or distances of the inner and outer contacts are optimized, the probability of an open connection is reduced significantly. In one embodiment, this probability may be less than 10%. The length of the nanowire 130 may be long or short. The definition of “long” or “short” is relative and not absolute. It may be defined with respect to the geometry of the contact structure, such as the largest diameter of the outer contact, and the channel length. In one embodiment, the length of the nanowire 130 may be long which is approximately greater than, or equal to, the largest diameter D_{L} of the outer contact 120. In another embodiment, the length of the nanowire 130 may be short which is approximately less than, or equal to, half of the largest diameter D_{L} of the outer contact 120 and greater than the channel length. For nanowires with short lengths, a technique using AC source with a single terminal connected to the inner contact as illustrated in FIGS. 22, 23, and 25, may be employed.

FIG. 2 is a diagram illustrating a misalignment error curve according to one embodiment. The horizontal axis corresponds to the distance from the edge of the center 115. The vertical axis corresponds to the ratio p=D/Dₘᵢₙ where Dₘᵢₙ is the minimum distance. The rᵢₙₙₑᵣ is the radius of the center 115 and the rₒᵤₜₑᵣ is the radius of the outer contact 120 around the center 115, assuming a circular geometry.

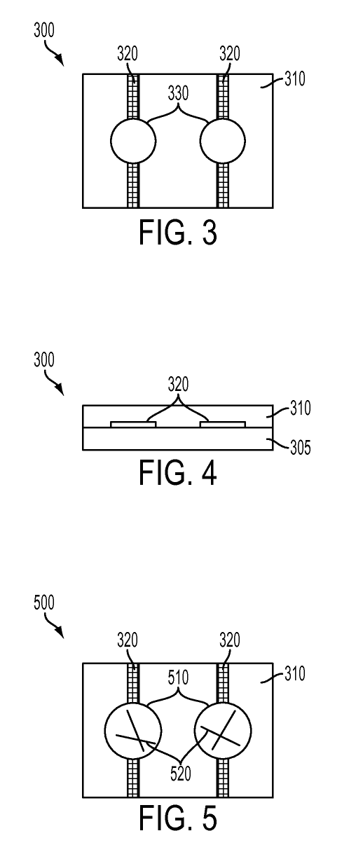

The contact structure shown in FIG. 1 may be used to form connections between the source and drain electrodes of a semiconductor device. The process of fabricating a semiconductor device having nanowires as radial connections for the electrodes may be illustrated in FIGS. 3 through FIGS. 10.

FIGS. 3 and 4 are diagrams illustrating a top view and a side view, respectively, of patterned gate electrodes 300 according to one embodiment. Gate electrodes 320 are patterned and formed on a substrate 305. A gate dielectric layer 310 is deposited on the substrate 305 and the gate electrodes 320. The regions 330 are directly above the gate electrodes 320 on the surface of the dielectric layer 310.

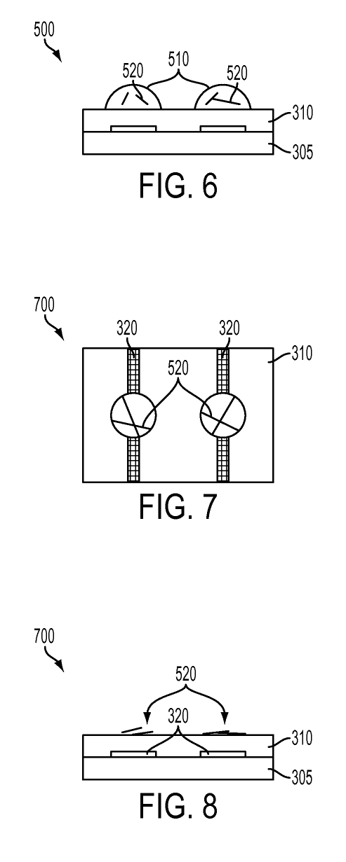

FIGS. 5 and 6 are diagrams illustrating a top view and a side view, respectively, of liquid having nanowires on the patterned gate electrodes 500 according to one embodiment. Liquids or drops of liquid 520 are deposited on the regions 320 which are aligned or in registration with the gate electrodes 310. The liquids 520 may be deposited using ink jet printing or flexographic printing from an elastomeric plate. The liquids 520 may contain a single or multiple nanowires 510.

FIGS. 7 and 8 are diagrams illustrating a top view and a side view, respectively, of liquid evaporated leaving nanowires on the patterned gate electrodes 700 according to one embodiment. The liquids 510 are evaporated, leaving the nanowires 510 on the surface of the dielectric layer 310, localized at the regions 320. These nanowires 510 may be randomly arranged at the locations directly above the gate electrodes 310.

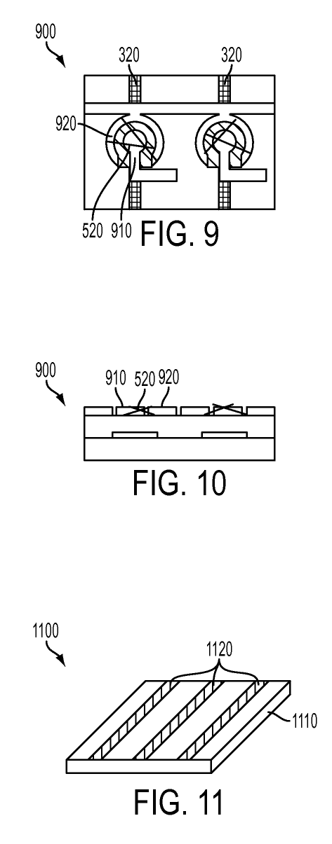

FIGS. 9 and 10 are diagrams illustrating a top view and a side view, respectively, of source and drain electrodes deposited on the gate dielectric 900 according to one embodiment. The metals and bus lines and source electrodes 910 and drain electrodes 920 may be deposited on the dielectric layer 310 using standard photolithographic processes. The source electrodes 910 and drain electrodes 920 have contacts formed according to a geometry similar to the contact structure shown in FIG. 1. The nanowires 510 form connections to connect source electrodes 910 and drain electrodes 920 in a rotationally invariant geometry. In one embodiment, the length of the nanowire 520 may be approximately greater than, or equal to, the largest diameter D_{L} of the drain electrode 920, or the outer contact. In another embodiment, the length of the nanowire 520 may be approximately less than, or equal to, half of the largest diameter D_{L} of the drain electrode 920, or the outer contact, and greater than the channel length.

The nanowires 510 may be deposited on the dielectric layer 310 or the substrate 305 using a printing technique as illustrated in FIGS. 11 to 14.

FIG. 11 is a diagram illustrating gate electrodes patterned on a substrate 1100 according to one embodiment. Gate electrodes 1120 are patterned on a substrate 1110 using conventional techniques.

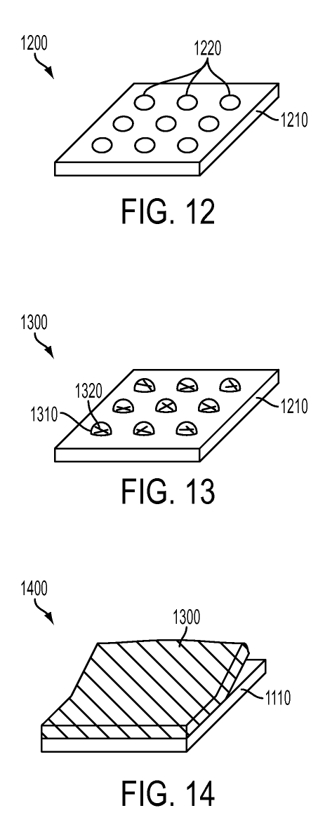

FIG. 12 is a diagram illustrating microwells formed on a flexographic plate 1200 according to one embodiment. Microwells 1220 may be formed on a flexographic plate 1210. The flexographic plate 1210 may be made by a suitable polymeric compound such as Polydimethylsiloxane (PDMS). Each of the microwells 1220 may have a volume of less than 1 nL. The microwells 1220 may be formed to correspond to the gate electrodes 1120. In other words, they may be aligned or registered to match in geometry with the gate electrodes 1120.

FIG. 13 is a diagram illustrating liquid deposited into the microwells 1300 according to one embodiment. Liquids or drops of liquid 1310 containing nanowires 1320 are then deposited into the microwells 1220.

FIG. 14 is a diagram illustrating the flexographic plate being transferred onto the substrate according to one embodiment. The plate 1300 including the flexographic plate 1210 and the liquids 1310 with nanowires 1320 in microwells 1120 is then transferred onto the substrate 1110 with the patterned gate electrodes 1120. The transfer may be made by printing.

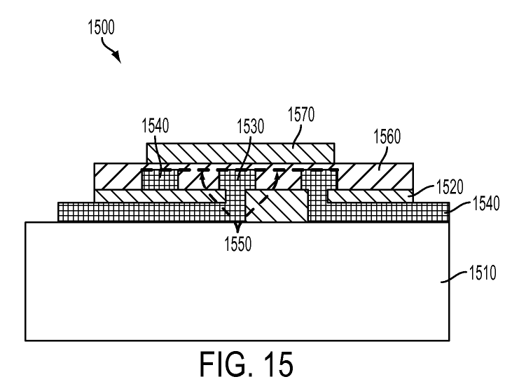

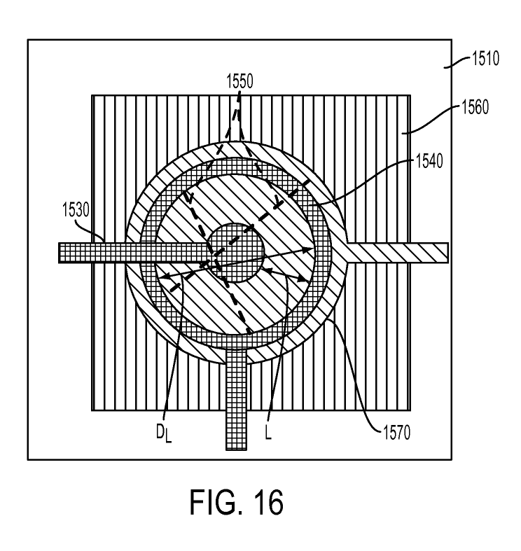

The process shown in FIGS. 3 through 10 may be used to fabricate a semiconductor device with gate electrode at the bottom. A process to construct a semiconductor device with a top gate electrode structure may be performed as illustrated in FIGS. 15 and 16. A top gate electrode structure may allow the drain contact (e.g., n-channel device) to completely surround the source electrode. This structure may have interconnect lines separated from the source-drain region in order to allow a co-planar circular Field-Effect Transistor (FET) design.

FIGS. 15 and 16 are diagrams illustrating a side view and a top view, respectively, of a device 1500 having a top gate electrode according to one embodiment.

An isolation barrier layer 1520 may be deposited on a substrate 1510. A source-drain assembly may be deposited on the substrate 1510 and within the isolation barrier layer 1520. The source-drain assembly have source electrode 1530 and drain electrodes 1540 connected via a nanowire 1550 in a rotationally invariant geometry. In one embodiment, the length of the nanowire 1550 may be approximately greater than, or equal to, the largest diameter D_{L} of the drain electrode 1540. In another embodiment, the length of the nanowire 1550 may be approximately less than, or equal to, half of the largest diameter D_{L} of the drain electrode 1540, or the outer contact, and greater than the channel length.

A dielectric layer 1560 may be deposited on the source-drain assembly. A gate electrode 1530 may be deposited on the dielectric layer 1560.

It is noted that that the structures shown in FIGS. 9, 15, and 16 may be patterned while the array of the source/drain contacts for the nanowire devices is biased with a voltage. The bias may create an electric field across the channel region that may provide a force that aligns the nanowires parallel to the electric field (in a normal direction to the metal contacts). In addition, any of the devices shown above may be repeated over a defined area to create an array of individually addressable devices, such as an array of transistors used in image pixel array.

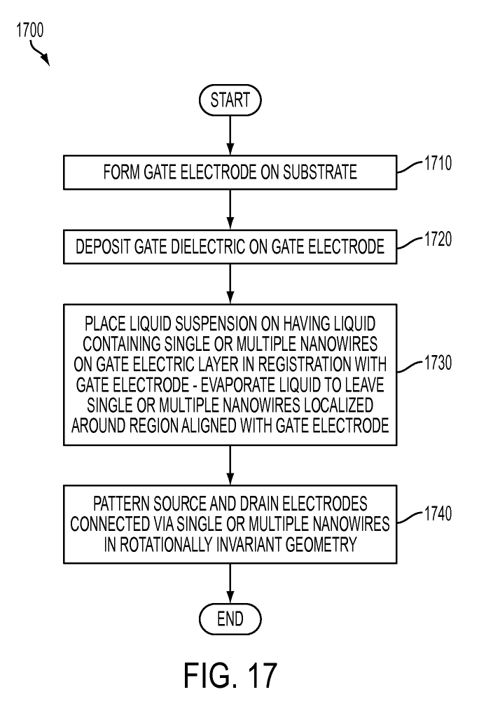

FIG. 17 is a flowchart illustrating a process 1700 to fabricate a device with a bottom gate structure according to one embodiment.

Upon START, the process 1700 forms a gate electrode on a substrate (Block 1710). Next, the process 1700 deposits a gate dielectric layer on the gate electrode (Block 1720). Then, the process 1700 places a liquid suspension having a liquid containing a single or multiple nanowires on the gate dielectric layer in registration with the gate electrode (Block 1730). This may include evaporating the liquid to leave the single or multiple nanowires localized around a region aligned with the gate electrode.

Next, the process 1700 patterns source and drain electrodes connected via the single or multiple nanowires in a rotationally invariant geometry (Block 1740). The process 1700 is then terminated.

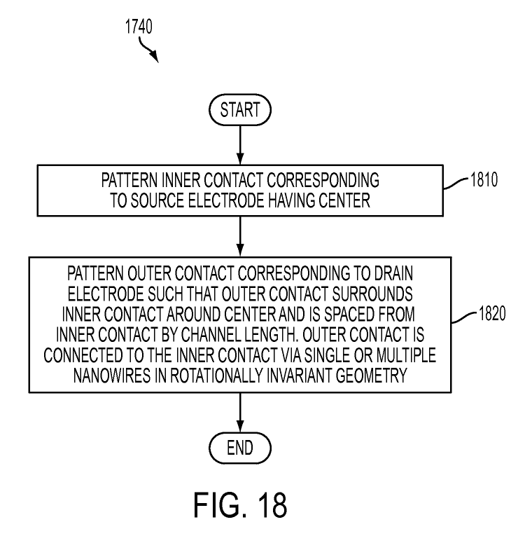

FIG. 18 is a flowchart illustrating a process 1740 to pattern source and drain electrodes according to one embodiment.

Upon START, the process 1740 patterns an inner contact corresponding to the source electrode having a center (Block 1810). Next, the process 1740 patterns an outer contact corresponding to the drain electrode such that the outer contact surrounds the inner contact around the center and is spaced from the inner contact by a channel length (Block 1820). The outer contact is connected to the inner contact via the single or multiple nanowires in the rotationally invariant geometry. The process 1740 is then terminated. The resulting contact structure is similar to that of FIG. 1.

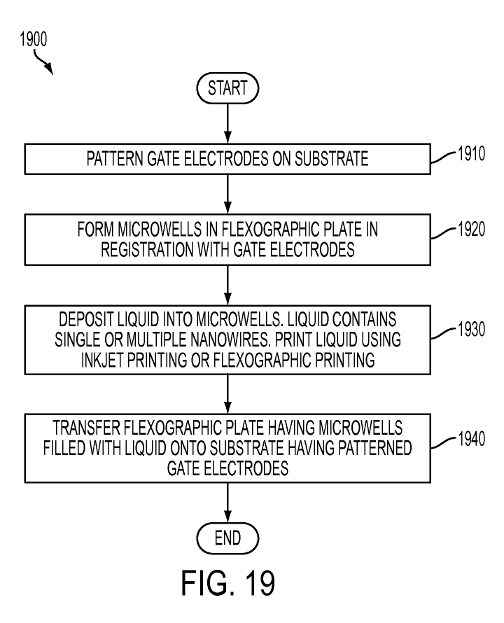

FIG. 19 is a flowchart illustrating a process 1900 to deposit liquid by printing according to one embodiment.

Upon START, the process 1900 patterns gate electrodes on a substrate (Block 1910). Next, the process 1900 forms microwells in a flexographic plate in registration with the gate electrodes (Block 1920). Then, the process 1900 deposits liquid into the microwells (Block 1930). The liquid contains a single or multiple nanowires. This may be performed by printing the liquid using inkjet printing or flexographic printing.

Next, the process 1900 transfers the flexographic plate having the microwells filled with the liquid onto the substrate having the patterned gate electrodes (Block 1940). The process 1900 is then terminated.

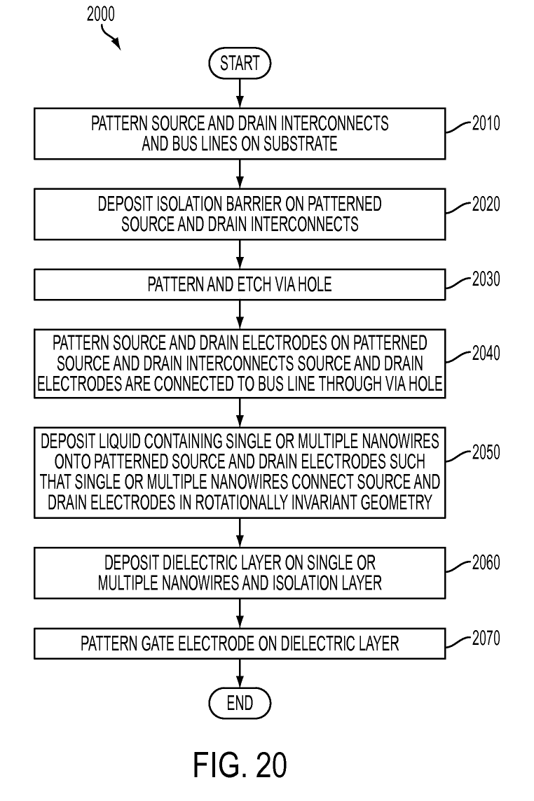

FIG. 20 is a flowchart illustrating a process 2000 to fabricate a device with a top gate structure according to one embodiment.

Upon START, the process 2000 patterns source and drain interconnects and a bus line on a substrate (Block 2010). Next, the process 2000 deposits an isolation barrier on the patterned source and drain interconnects (Block 2020). Then, the process 2000 patterns and etches a via hole (Block 2030). Next, the process 2000 patterns source and drain electrodes on the patterned source and drain interconnects (Block 2040). The source and drain electrodes are connected to the bus line through the via hole. The patterning of the source and drain electrodes may be performed using a process operation similar to the process 1740 shown in FIG. 18. The source and drain electrodes have a contact structure similar to that of FIG. 1.

Then, the process 2000 deposits liquid containing a single or multiple nanowires onto the patterned source and drain electrodes such that the single or multiple nanowires connect the source and drain electrodes in a rotationally invariant geometry (Block 2050). Next, the process 2000 deposits a dielectric layer on the single or multiple nanowires and the isolation layer (Block 2060). Then, the process 2000 patterns a gate electrode on the dielectric layer (Block 2070). The process 2000 is then terminated.

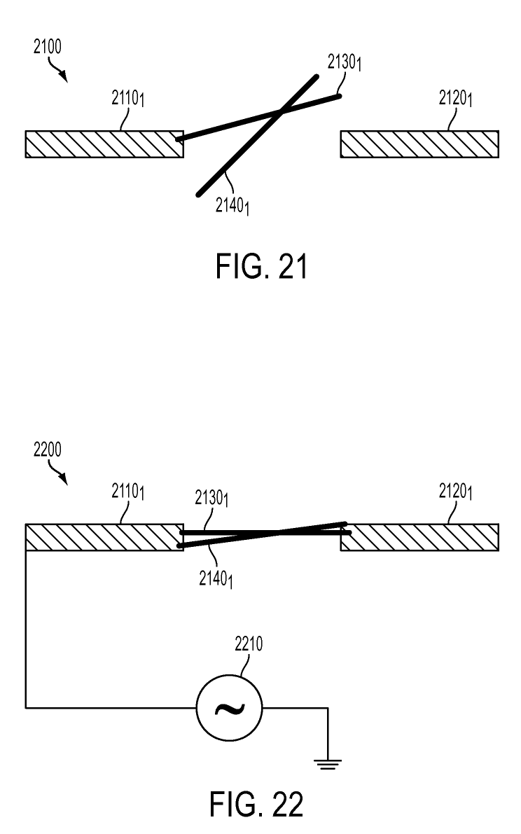

FIG. 21 is a diagram illustrating a structure 2100 of nanowires having short lengths in random orientation with respect to a pair of electrodes according to one embodiment. The structure 2100 includes electrodes, or contacts, 2110₁ and 2120₁, and nanowires 2130₁ and 2140₁.

The electrodes, or contacts, 2110₁ and 2120₁ may correspond to source and drain electrodes in a semiconductor device. The nanowires 2130₁ and 2140₁ may have short lengths. As described above, for contact or electrode structures that do not have a rotationally invariant geometry, the distinction of short and long nanowires may not be relevant. The nanowires 2130₁ and 2140₁ are shown to be in random orientation with respect to the electrodes 2110₁ and 2120₁. In this configuration, no reliable contacts may be formed to connect the electrodes or contacts together via the nanowires 2130₁ and 2140₁ whether or not the contact or electrode structure has a rotationally invariant geometry. The nanowires 2130₁ and 2140₁ may be immersed or embedded in a liquid or solution to form a suspension. When a drop of the suspension is placed between the source and drain electrodes or the contacts, the nanowires 2130₁ and 2140₁ may be dispersed randomly and may not be aligned so as to form a connection between the two electrodes.

FIG. 22 is a diagram illustrating a structure 2200 showing alignment of nanowires having short lengths with respect to a pair of electrodes using AC source with only one terminal connected to electrodes according to one embodiment. The structure 2200 is similar to the structure 2100 except that an alternating current (AC) source 2210 is applied to the contact or electrode structure.

The AC source 2210 may be any suitable AC source with appropriate voltage level or power or frequency. The AC source 2210 may create an electric field across the electrodes or contacts. This AC electric field may induce a dielectrophoretic force on the nanowires 2130₁ and 2140₁. This dielectrophoretic force may position and align the between the source and drain electrodes such that the nanowires are oriented with one end at the source electrode or the inner contact if the geometry is rotationally invariant, and one end at the drain electrode or the outer contact if the geometry is rotationally invariant.

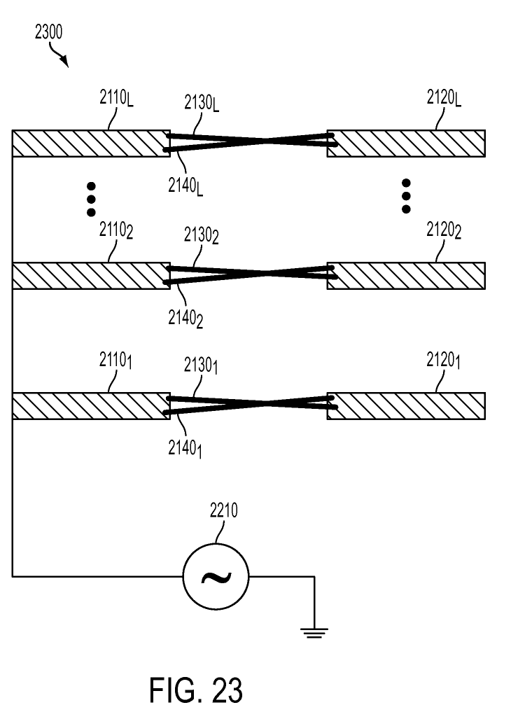

The AC source 2210 is applied to the contact or electrode structure such that only one terminal of the AC source 2210 is connected to the contact or electrode structure. The other terminal of the AC source 2210 is left floating. The floating terminal may become capacitively coupled to the driven terminal and may thus be able to act as a local ground resulting in aligned nanowires between the two contacts or the source and drain electrodes 2110₁ and 2120₁. This approach is advantageous because it significantly reduces the complexity of interconnects needed to align nanowires in an array or a plurality of pairs of electrodes or contacts as illustrated in FIG. 23.

FIG. 23 is a diagram illustrating a structure 2300 showing alignment of nanowires having short lengths with respect to multiple pairs of electrodes using a single AC source with only one terminal connected to electrodes according to one embodiment. The structure 2300 includes a single AC source 2210 and L groups of electrode pairs 2110ₖ and 2120ₖ (k=1, . . . L) and nanowires 2130ₖ and 2140ₖ (k=1, . . . L) where L is a positive integer. The structure 2300 may be suitable for devices that have multiple electrode pairs such as an array of transistors (e.g., image pixel array).

The AC source 2210 may be applied to the L groups of electrode pairs 2110ₖ and 2120ₖ (k=1, . . . L) and nanowires 2130ₖ and 2140ₖ (k=1, . . . L) by connecting one terminal to all electrodes 2110ₖ (k=1, . . . L). The other terminal of the AC source 2210 is left floating and/or connected to ground. The other electrodes 2120ₖ (k=1, . . . L) are left unconnected to the AC source 2210. In this construction, only one terminal of the devices in the array may need to be joined in order to align the nanowires, leading to efficient fabrication of an array of individual devices with a common source (or drain).

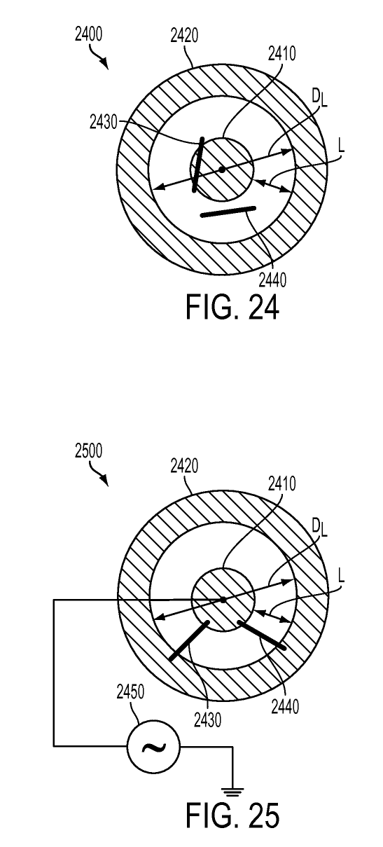

FIG. 24 is a diagram illustrating a structure 2400 showing nanowires having short lengths in random orientation with respect to electrodes in rotationally invariant geometry according to one embodiment. The structure 2400 includes an inner contact, or electrode (e.g., source electrode) 2410, an outer contact, or electrode (e.g., drain electrode) 2420, and nanowires 2430 and 2440. The contact or electrode structure has a rotationally invariant geometry. For illustrative purposes, they are shown as circles or annular rings. The largest diameter of the outer contact or electrode 2420 is D_{L} and the channel length is L as shown.

If the length of the nanowires 2430 and 2440 is short, i.e., if it is approximately less than, or equal to, half of the largest diameter D_{L} of the outer contact and greater than the channel length L), placing the nanowires 2430 and 2440 in the vicinity, or near, or between the inner and outer contacts (or electrodes) may not form reliable connections. Since the length is short, it is possible that the nanowires 2430 and 2440 are oriented such that they do not connect the contacts or the electrodes as shown in FIG. 24.

FIG. 25 is a diagram illustrating a structure 2500 showing nanowires having short lengths in alignment with respect to electrodes in rotationally invariant geometry using an AC source with only one terminal connected to electrodes according to one embodiment. The structure 2500 includes the inner contact, or electrode (e.g., source electrode) 2410, the outer contact, or electrode (e.g., drain electrode) 2420, the nanowires 2430 and 2440, and an AC voltage source 2450. The contact or electrode structure has a rotationally invariant geometry as in FIG. 24.

The AC voltage source 2450 is applied to the contact structure to cause the single or multiple nanowires 2430 and 2440 to align and connect the inner contact 2410 to the outer contact 2420. The AC source 2450 has a first terminal connected to the inner contact 2410 and a second terminal not connected to the inner and/or outer contacts. The second terminal may be left floating (open) or connected to ground. As discussed above, the AC voltage source 2450 creates an AC electric field that induces a dielectrophoretic force on the nanowires 2430 and 2440. This dielectrophoretic force may position and align the between the inner contacts 2410 and 2420 (or the source and drain electrodes) such that the nanowires 2430 and 2440 are oriented with one end at the source electrode or the inner, and one end at the drain electrode or the outer contact. The alignment is radial, emanating from the center of the inner contact 2410.

By applying the AC power source to a single terminal, it may be possible to easily fabricate a large array of devices in a rotationally invariant geometry. The rotationally invariant geometry is well suited for the dielectrophoretic alignment because it eliminates the need to consider the effects of fringe fields that may be present at sharp corners of the electrodes. Accordingly, the alignment yield may be higher than the traditional tecniques.

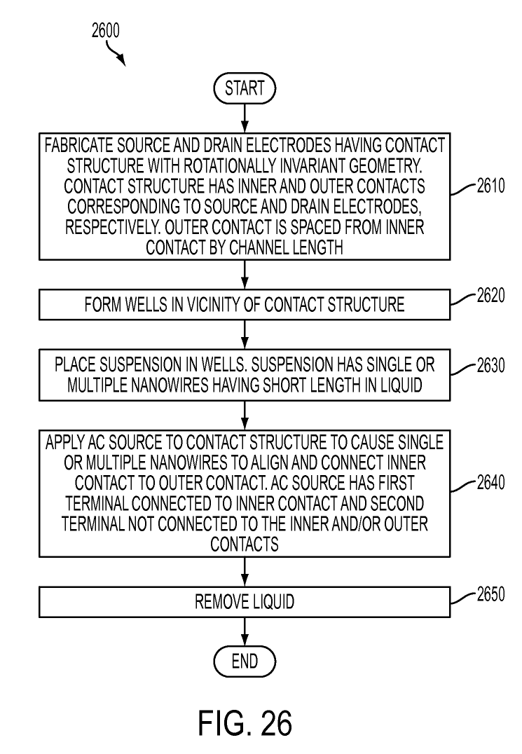

FIG. 26 is a flowchart illustrating a process 2600 to align nanowires having short lengths according to one embodiment.

Upon START, the process 2600 fabricates source and drain electrodes having a contact structure with a rotationally invariant geometry (Block 2610). The contact structure has inner and outer contacts corresponding to the source and drain electrodes, respectively. The outer contact is spaced from the inner contact by a channel length L.

Next, the process 2600 forms wells in vicinity of the contact structure (Block 2620). Then, the process 2600 places a suspension in the wells (Block 2630). The suspension has single or multiple nanowires having a short length in a liquid.

Next, the process 2600 applies an alternating current (AC) source to the contact structure to cause the single or multiple nanowires to align and connect the inner contact to the outer contact (Block 2640). The AC source has a first terminal connected to the inner contact and a second terminal not connected to the inner and/or outer contacts. Then, the process 2600 removes the liquid leaving the nanowires aligned and forming connections (Block 2650). The liquid may be removed by any suitable methods such as evaporation, suction, or forced air. The process 2600 is then terminated.

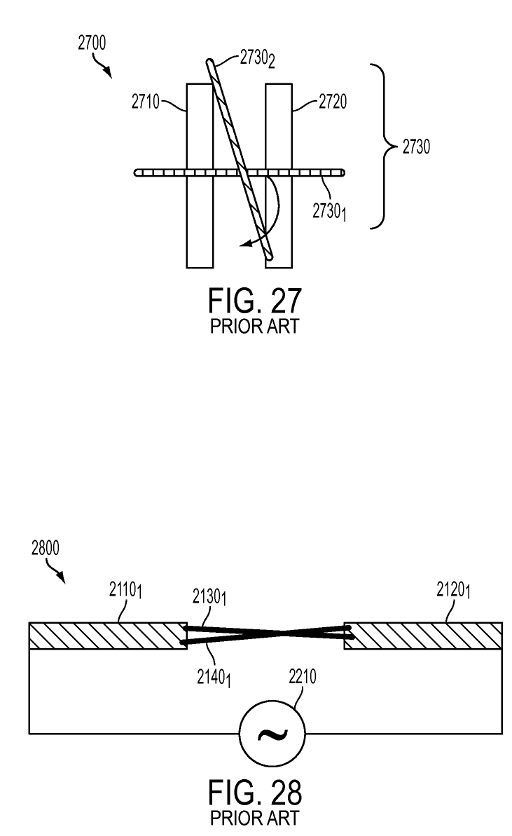

FIG. 27 is a diagram illustrating a top view of linear contacts in a prior art embodiment. In this prior art contact structure, the contacts 2710 and 2720 may be linear segments. A connecting wire 2730 may be used to connect the contacts 2710 and 2720. The wire 2730 may have two positions 2730₁ and 2730₂. Position 2730₁ may provide a good connection because it is orthogonal to both contacts 2710 and 2720. However, if the wire 2730 is rotated, such as when it is move to the position 2730₂, the connection may become marginal. Position 2730₂ is shown where it barely touches the contacts 2710 and 2720. As the wire 2730 is rotated further, it may not touch one or both of the contacts 2710 and 2720, resulting in an open circuit. The geometry of the device may also be changed significantly between position 2730₂ and position 2730₁. The difference in the channel geometry for each position may vary by √2 for a square geometry (channel width, W, to channel length, L, ratio=1). The maximum variation increases as the ratio between W/L increases.

FIG. 28 is a diagram illustrating a structure 2800 alignment of nanowires using an AC source with two terminals connected to electrodes in a prior art embodiment. The structure 2800 includes electrodes, or contacts, 2110₁ and 2120₁, and nanowires 2130₁ and 2140₁ and the AC source 2210 similar to the structure 2100. The main difference is that the two terminals of the AC source 2210 are connected to the corresponding two electrodes, or contacts, 2110₁ and 2120₁. This prior art embodiment is not very useful because for constructing an array of devices, it requires either all devices to be parallel or requires the application of an AC signal between each individual source and drain electrodes. This construction may not be practical or possible depending on the array design.

It will be appreciated that various of the above-disclosed and other features and functions, or alternatives thereof, may be desirably combined into many other different systems or applications. Various presently unforeseen or unanticipated alternatives, modifications, variations, or improvements therein may be subsequently made by those skilled in the art which are also intended to be encompassed by the following claims.

What is claimed is:

1. An apparatus comprising:
an inner contact having a center;
an outer contact surrounding the inner contact around the center and spaced from the inner contact by a channel length; and
a nanowire having a length connecting the center of the inner contact and the outer contact such that connection between the inner contact and the outer contact is rotationally invariant.

2. The apparatus of claim 1 wherein the nanowire crosses the center of the inner contact and connects to at least one point on the outer contact.

3. The apparatus of claim 1 wherein the outer contact surrounds the inner contact completely or partially leaving at least one opening.

4. The apparatus of claim 1 wherein the outer contact surrounds the inner contact such that the channel length is uniform or non-uniform within a pre-defined tolerance.

5. The apparatus of claim 1 wherein the outer contact surrounds the inner contact circularly.

6. A semiconductor device comprising:
a gate electrode deposited on a substrate;
a dielectric layer deposited on the substrate and the gate electrode; and
a source-drain assembly deposited on the dielectric layer, the source-drain assembly having source and drain electrodes connected in a contact geometry via a nanowire having a length in a rotationally invariant geometry.

7. The device of claim 6 wherein the source-drain assembly comprises:
an inner contact corresponding to the source electrode having a center; and
an outer contact corresponding to the drain electrode, the outer contact circularly surrounding the inner contact around the center and spaced from the inner contact by a channel length; wherein the nanowire connects the center of the inner contact and the outer contact in the rotationally invariant geometry.

8. The device of claim 7 wherein the nanowire crosses the center of the inner contact and connects to at least one point on the outer contact.

9. The device of claim 7 wherein the outer contact surrounds the inner contact completely or partially leaving at least one opening.

10. The device of claim 7 wherein the outer contact surrounds the inner contact such that the channel length is uniform or non-uniform within a pre-defined tolerance.

11. A semiconductor device comprising:
an isolation barrier layer deposited on a substrate;
a source-drain assembly deposited on the substrate and within the isolation barrier layer, the source-drain assembly having source and drain electrodes connected via a nanowire having a length in a rotationally invariant geometry;
a dielectric layer deposited on the source-drain assembly; and
a gate electrode deposited on the dielectric layer.

12. The device of claim 11 wherein the source-drain assembly comprises:
an inner contact corresponding to the source electrode having a center; and
an outer contact corresponding to the drain electrode, the outer contact circularly surrounding the inner contact around the center and spaced from the inner contact by a channel length; wherein the nanowire connects the center of the inner contact and the outer contact in the rotationally invariant geometry.

13. The device of claim 12 wherein the nanowire crosses the center of the inner contact and connects to at least one point on the outer contact.

14. The device of claim 12 wherein the outer contact surrounds the inner contact completely or partially leaving at least one opening.

15. The device of claim 12 wherein the outer contact surrounds the inner contact such that the channel length is uniform or non-uniform within a pre-defined tolerance.

16. A method comprising:
forming a gate electrode on a substrate;
depositing a gate dielectric layer on the gate electrode;
placing a liquid suspension having a liquid containing a single or multiple nanowires on the gate dielectric layer in registration with the gate electrode; and
patterning source and drain electrodes connected via the single or multiple nanowires in a rotationally invariant geometry.

17. The method of claim 16 wherein placing the liquid suspension comprises:
evaporating the liquid to leave the single or multiple nanowires localized around a region aligned with the gate electrode.

18. The method of claim 17 wherein patterning the source and drain electrodes comprises:
patterning an inner contact corresponding to the source electrode having a center; and
patterning an outer contact corresponding to the drain electrode such that the outer contact surrounds the inner contact around the center and is spaced from the inner contact by a channel length, the outer contact connected to the inner contact via the single or multiple nanowires in the rotationally invariant geometry.

19. The method of claim 18 wherein the outer contact surrounds the inner contact such that the channel length is uniform or non-uniform within a pre-defined tolerance.

20. A method comprising:
fabricating source and drain electrodes having a contact structure with a rotationally invariant geometry, the contact structure having inner and outer contacts corresponding to the source and drain electrodes, respectively, the outer contact spaced from the inner contact by a channel length;
forming wells in vicinity of the contact structure;
placing a suspension in the wells, the suspension having single or multiple nanowires having a short length in a liquid; and
applying an alternating current (AC) source to the contact structure to cause the single or multiple nanowires to align and connect the inner contact to the outer contact, the AC source having a first terminal connected to the inner contact and a second terminal not connected to the inner and/or outer contacts.

21. The method of claim 20 further comprising:
removing the liquid.

22. The method of claim 20 wherein the short length is approximately less than, or equal to, half of a largest diameter of the outer contact and greater than the channel length.

23. The method of claim 20 wherein the second terminal is left floating or connected to ground.
